(19) United States
(12) Patent Application Publication
(10) Pub. No.: US 2023/0240010 A1
(43) Pub. Date: Jul. 27, 2023

(54) SYSTEMS AND METHODS FOR PROCESSING PRINTED CIRCUIT BOARD FOR MODULAR CIRCUITS

(71) Applicant: Dell Products L.P., Round Rock, TX (US)

(72) Inventors: Yu-Lin TSAI, New Taipei City (TW); Chia-Ping LIN, Taipei City (TW); Kuo-Yeh HUNG, Taipei City (TW)

(73) Assignee: Dell Products L.P., Round Rock, TX (US)

(21) Appl. No.: 17/582,495

(22) Filed: Jan. 24, 2022

(51) Int. Cl. H05K 1/11; H05K 3/40

(52) U.S. Cl. CPC H05K 1/111; H05K 3/4007

(57) ABSTRACT

A circuit board may include a pad board portion comprising one or more pads and a circuit module portion within the pad board portion and comprising a circuit electrically coupled to the one or more pads. The pad board portion and circuit module portion may be arranged such that they can be separated from each other in a manner such that the pad board portion is configured to electrically couple to a circuit module surface mounted to the pad board portion via the one or more pads and the circuit module portion is configured to electrically couple to a pad board via pads of the pad board.

### TECHNICAL FIELD

The present disclosure relates in general to information handling systems, and more particularly to systems and methods for manufacturing and processing a printed circuit board for modular circuits.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

An information handling system may include one or more circuit boards operable to mechanically support and electrically couple electronic components making up the information handling system. For example, circuit boards may be used as part of motherboards, memories, storage devices, storage device controllers, peripherals, peripheral cards, network interface cards, and/or other electronic components. As is known in the art, a circuit board may comprise a plurality of conductive layers separated and supported by layers of insulating material laminated together, with conductive traces disposed on and/or in any of such conductive layers.

A circuit board may have numerous electrically conductive conduits, including traces, vias, pads, and/or other electrically-conductive conduits. A via may comprise a substantially electrically conductive material and may be formed such that vias may electrically couple together traces on different layers of a circuit board, thus allowing signals to propagate between layers of a circuit board.

To allow flexibility in development effort and use, it may be desirable to maximize circuit board interchangeability. Accordingly, systems and methods that enable maximization of circuit board interchangeability are desired.

### SUMMARY

In accordance with the teachings of the present disclosure, the disadvantages and problems associated with existing techniques for circuit board manufacturing and processing may be reduced or eliminated.

In accordance with embodiments of the present disclosure, a circuit board may include a pad board portion comprising one or more pads and a circuit module portion within the pad board portion and comprising a circuit electrically coupled to the one or more pads. The pad board portion and circuit module portion may be arranged such that they can be separated from each other in a manner such that the pad board portion is configured to electrically couple to a circuit module surface mounted to the pad board portion via the one or more pads and the circuit module portion is configured to electrically couple to a pad board via pads of the pad board.

In accordance with these and other embodiments of the present disclosure, a method may include forming one or more pads in a pad board portion of a circuit board, forming a circuit electrically coupled to the one or more pads in a circuit module portion with the pad board portion, arranging the pad board portion and circuit module portion such that they can be separated from each other in a manner such that the pad board portion is configured to electrically couple to a circuit module surface mounted to the pad board portion via the one or more pads and the circuit module portion is configured to electrically couple to a pad board via pads of the pad board.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1A illustrates a plan view of a bottom surface of an example manufactured circuit board, in accordance with embodiments of the present disclosure;

FIG. 1B illustrates a plan view of a top surface of the example manufactured circuit board of FIG. 1A, in accordance with embodiments of the present disclosure;

FIG. 1C illustrates a side elevation view of the example manufactured circuit board of FIGS. 1A and 1B, in accordance with embodiments of the present disclosure;

FIG. 2 illustrates a plan view of a module board resulting from cutting the manufactured circuit board of FIGS. 1A-1C to isolate the module board from the remainder of the manufactured circuit board, in accordance with embodiments of the present disclosure;

FIG. 3 illustrates a plan view of a pad board resulting from isolating the module board from the remainder of the manufactured circuit board, in accordance with embodiments of the present disclosure;

FIG. 4A illustrates a plan view of a portion of a top surface of the pad board of FIG. 3 with the module board of FIG. 2 surface mounted to the module board, in accordance with embodiments of the present disclosure; and

FIG. 4B illustrates a side elevation view of the pad board of FIG. 3 with the module board of FIG. 2 surface mounted to the module board, in accordance with embodiments of the present disclosure.

### DETAILED DESCRIPTION

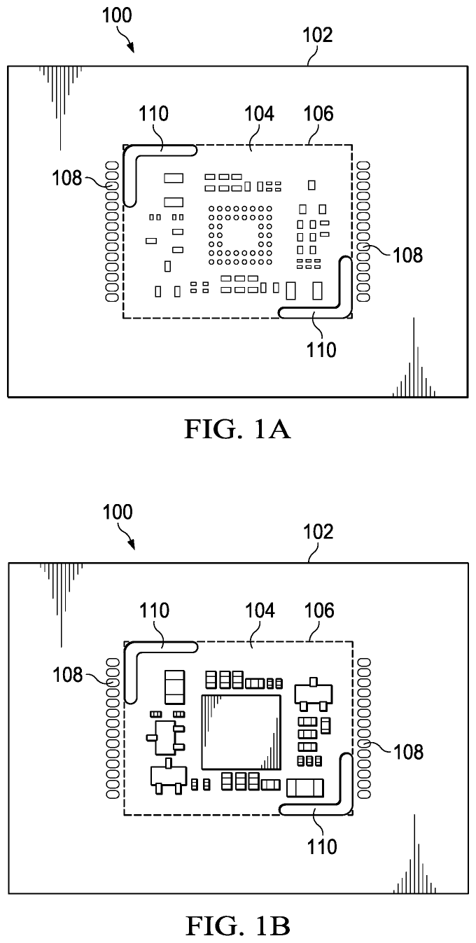

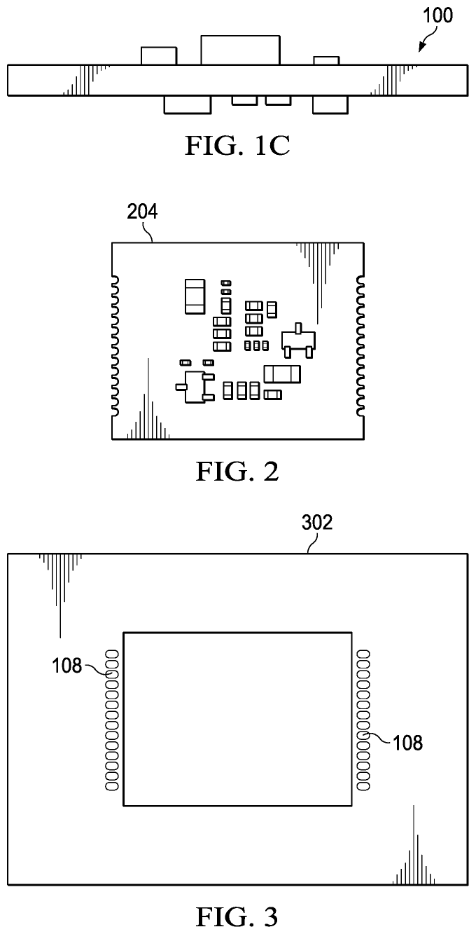

Preferred embodiments and their advantages are best understood by reference to FIGS. 1A through 4B, wherein like numbers are used to indicate like and corresponding parts.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems, buses, memories, I/O devices and/or interfaces, storage resources, network interfaces, motherboards, and/or any other components and/or elements of an information handling system.

As discussed above, an information handling system may include one or more circuit boards operable to mechanically support and electrically connect electronic components making up the information handling system (e.g., packaged integrated circuits). Circuit boards may be used as part of motherboards, memories, storage devices, storage device controllers, peripherals, peripheral cards, network interface cards, and/or other electronic components. As used herein, the term “circuit board” includes printed circuit boards (PCBs), printed wiring boards (PWBs), etched wiring boards, and/or any other board or similar physical structure operable to mechanically support and electrically couple electronic components.

FIG. 1A illustrates a plan view of a bottom surface of an example manufactured circuit board 100, in accordance with embodiments of the present disclosure. FIG. 1B illustrates a plan view of a top surface of example manufactured circuit board 100, in accordance with embodiments of the present disclosure. FIG. 1C illustrates a side elevation view of example manufactured circuit board 100, in accordance with embodiments of the present disclosure.

As shown in FIGS. 1A and 1B, manufactured circuit board 100 may include a pad board portion 102 and a module board portion 104 separated by a border 106. As also shown in FIGS. 1A and 1B, pad board portion 102 may include a plurality of pads 108 formed on one or both surfaces thereof. Further, although not explicitly shown in FIGS. 1A and 1B for purposes of clarity and exposition, pad board portion 102 may include electrical conduits (e.g., other pads, traces, vias, etc.) and/or other electronic components (e.g., surface-mounted circuit devices and/or integrated circuit packages) electrically coupled to one or more of such pads 108.

As further depicted in FIGS. 1A and 1B, module board portion 104 may include a circuit of electrical conduits (e.g., pads, traces, vias, etc.) and/or other electronic components (e.g., surface-mounted circuit devices and/or integrated circuit packages), which are not explicitly labeled in the figures for purposes of clarity and exposition.

As also depicted in FIGS. 1A and 1B, manufactured circuit board 100 may include one or more separation guides 110 formed proximate to border 106. Each separation guide 110 may comprise an opening or void formed through one or more (and in the embodiments depicted, all) layers of manufactured circuit board 100. Each separation guide 110 may be shaped to indicate a feature of border 106 (e.g., a linear edge of a separation guide 110 may be approximately co-linear with an edge of border 106).

Further, although not explicitly shown in FIGS. 1A and 1B, the circuit of module board portion 104 may be electrically coupled to one or more pads 108 by way of traces formed on the top surface layer and/or bottom surface layer of manufactured circuit board 100. In some embodiments, layers of manufactured circuit board 100 other than the top surface layer and bottom surface layer may be absent of electrical conduits coupling the circuit of module board portion 104 to pads 108.

In addition, while also not explicitly shown in FIGS. 1A and 1B, manufactured circuit board 100 may include one or more connectors for electrically coupling to other circuit boards (e.g., an edge connector of manufactured circuit board 100 configured to be received in a receptacle connector of another circuit board).

Accordingly, in some embodiments, manufactured circuit board 100 may be used (e.g., in an information handling system or other electronic system) in substantially the form shown in FIGS. 1A-1C. However, in some embodiments, manufactured circuit board 100 may further be processed to separate module board portion 104 from pad board portion 102.

For example, an appropriate tool may be configured to, as indicated by separation guides 110, cut through layers of manufactured circuit board 100, to separate module board portion 104 from pad board portion 102, resulting in module board 204 depicted in FIG. 2 and pad board 302 depicted in FIG. 3.

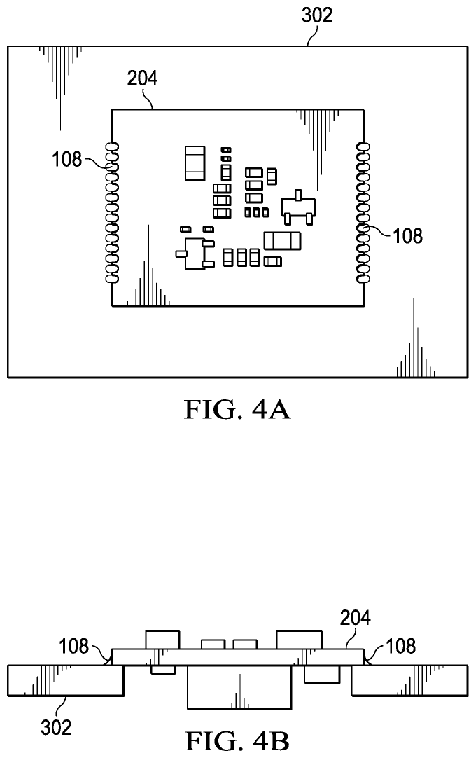

Once separated, module board 204 may be surface mounted to pads of a corresponding pad board, including pads 108 of pad board 302 from which module board 204 was separated as shown in FIGS. 4A and 4B, or another pad board. Likewise, pad board 302 may be electrically coupled, via its pads 108, to a corresponding module board, including module board 204 that was separated from pad board 302 as shown in FIGS. 4A and 4B, or another module board.

Accordingly, using the systems and methods described herein, a single printed circuit board may flexibly be used either in an unseparated state (e.g., as shown in FIGS. 1A and 1B) or in a separated state (as shown in FIGS. 2 and 3) as desired.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A circuit board, comprising:
a pad board portion comprising one or more pads; and
a circuit module portion within the pad board portion and comprising a circuit electrically coupled to the one or more pads;
wherein the pad board portion and circuit module portion are arranged such that they can be separated from each other in a manner such that:
the pad board portion is configured to electrically couple to a circuit module surface mounted to the pad board portion via the one or more pads; and
the circuit module portion is configured to electrically couple to a pad board via pads of the pad board.

2. The circuit board of claim 1, wherein:
the pad board comprises the pad board portion; and
the circuit module comprises the circuit module portion.

3. The circuit board of claim 1, wherein the circuit is electrically coupled to the one or more pads only via one or more surface layers of the circuit board.

4. The circuit board of claim 1, further comprising one or more separation guides formed as voids through one or more layers of the circuit board.

5. The circuit board of claim 4, wherein each of the one or more separation guides comprises a feature indicative of a border between the pad board portion and the circuit module portion.

6. A method comprising:
forming one or more pads in a pad board portion of a circuit board;
forming a circuit electrically coupled to the one or more pads in a circuit module portion with the pad board portion;
arranging the pad board portion and circuit module portion such that they can be separated from each other in a manner such that:
the pad board portion is configured to electrically couple to a circuit module surface mounted to the pad board portion via the one or more pads; and
the circuit module portion is configured to electrically couple to a pad board via pads of the pad board.

7. The method of claim 6, wherein:
the pad board comprises the pad board portion; and
the circuit module comprises the circuit module portion.

8. The method of claim 6, further comprising electrically coupling the circuit to the one or more pads only via one or more surface layers of the circuit board.

9. The method of claim 6, further comprising forming one or more separation guides as voids through one or more layers of the circuit board.

10. The method of claim 9, wherein each of the one or more separation guides comprises a feature indicative of a border between the pad board portion and the circuit module portion.

11. The method of claim 6, further comprising electrically coupling the pad board portion to the circuit module surface mounted to the pad board portion via the one or more pads.

12. The method of claim 6, further comprising electrically coupling the circuit module portion to the pad board via pads of the pad board.
